(19) United States
(12) Patent Application Publication
(10) Pub. No.: US 2005/0092281 A1
(43) Pub. Date: May 5, 2005

(54) Structure for preventing stress concentration in a corner

(76) Inventor: Seung Woo Choi, Yongin-city (KR)

Correspondence Address: MORGAN, LEWIS & BOCKIUS LLP (SF), 2 PALO ALTO SQUARE, PALO ALTO, CA, 94306, US

(21) Appl. No.: 10/983,223

(22) Filed: Nov. 4, 2004

(30) Foreign Application Priority Data
Nov. 4, 2003 (KR) 10-2003-0077693

(51) Int. Cl. F02F 7/00; H01L 21/76

(52) U.S. Cl. 123/195 R

(57) ABSTRACT

Stress concentration at a corner is significantly reduced since the corner is provided with a corner structure that has a stress concentration portion formed to at least one point of the corner to concentrate stress. A plurality of round portions are formed to both left and right sides with respect to the stress concentration portion such that a sectional area of the stress concentration portion may be enlarged.

### CROSS-REFERENCE TO RELATED APPLICATIONS

This application claims priority of Korean Application No. 10-2003-0077693, filed Nov. 4, 2003, the disclosure of which is incorporated herein by reference.

### FIELD OF THE INVENTION

Generally, the present invention relates to a structure for preventing stress concentration, and more particularly, to a structure for preventing stress concentration in corner of enhanced durability.

### BACKGROUND OF THE INVENTION

In general, a structure for preventing stress concentration is applied to a weaker portion of a material. As an example, in an engine cylinder block, one of the weakest portions thereof may be the corner of a mounting part for a bearing cap. Therefore structures for preventing stress concentration are under continuing investigation in order to prevent cracks from occurring at such a corner. Several structures for preventing stress concentration in a corner according to the prior art will be hereinafter described with reference to FIGS. 1A-1C.

Firstly, as shown in FIG. 1A, a corner 11 may be rounded off such that merely one round portion R is formed. However, such a structure can have a problem in that either end of the round portion R may be easily cracked by a stress concentration.

Secondly, as shown in FIG. 1B, a corner 12 may be chamfered to form a flat portion C, and then both ends of the flat portion C are rounded off to form round portions R. Such a structure can have a problem that the flat portion C may be easily cracked by a stress concentration. Particularly, when such structures are applied to an engine block that undergoes significant vibration, a crack is likely to occur at such corners. Since the corner of a mounting part for a bearing cap is one of the weakest portions of an engine and stress is concentrated there, such a corner of an engine may be easily cracked by the stress.

As shown in FIG. 1C, in a structure for preventing stress concentration in a corner according to the prior art, a corner 13 is roll-processed by a rolling machine such that a rounded sunken portion R is formed thereat. However, such a corner structure requires excessive costs because of the need for an expensive rolling machine and a complicated rolling process.

The information disclosed in this Background of the Invention section is only for enhancement of understanding of the background of the invention and should not be taken as an acknowledgement or any form of suggestion that this information forms the prior art that is already known in this country to a person of ordinary skill in the art.

### SUMMARY OF THE INVENTION

Embodiments of the present invention provide structures for preventing stress concentrations in a corner having non-limiting advantages of an enhanced durability and a reduced cost.

An exemplary structure for preventing stress concentration in a corner according to an embodiment of the present invention includes a stress concentration portion formed to at least one point of the corner to concentrate stress, and a plurality of round portions formed to both of left and right sides with respect to the stress concentration portion such that a sectional area of the stress concentration portion may be enlarged.

In a further embodiment, the stress concentration portion is formed at a center of the corner such that the stress is not biased.

In a still further embodiment, the plurality of round portions includes first and second round portions of the same size that are respectively formed at the left and right sides of the stress concentration portion.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIGS. 1A to 1C are sectional views of structures for preventing stress concentration in a corner according to the prior art;

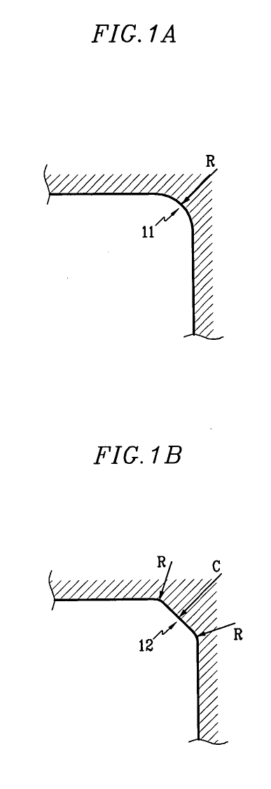

FIG. 2 is a sectional view of a structure for preventing stress concentration in a corner according to an embodiment of the present invention; and

FIG. 3 is a sectional view of an engine cylinder block applied with a structure for preventing stress concentration in a corner according to an embodiment of the present invention.

### DETAILED DESCRIPTION OF THE PREFERRED EMBODIMENTS

An embodiment of the present invention will hereinafter be described in detail with reference to the accompanying drawings.

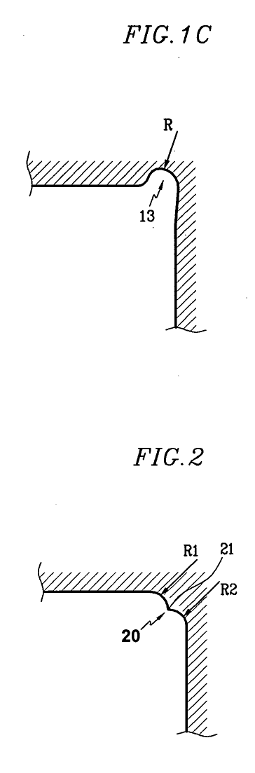

As shown in FIG. 2, a structure for preventing stress concentration in a corner according to an embodiment of the present invention includes a stress concentration portion 21 formed to at least one point in corner 20 to concentrate stress, and a plurality of round portions (see R1 and R2) formed to both of left and right sides with respect to the stress concentration portion 21 such that a sectional area of the stress concentration portion 21 may be enlarged. Stress concentration portion 21 is preferably formed at a center of the corner 20 such that the stress is not biased to either of the left and right sides.

Further, the plurality of round portions includes first and second round portions R1 and R2 respectively formed to the left and right sides of the stress concentration portion 21. As is apparent from the drawings, the sectional area of the stress concentration portion 21 may be enlarged by such first and second round portions R1 and R2. Consequently, the total sectional area of the corner 20 may also be increased. According to such features of the corner, even if a stress is concentrated to the corner 20, a crack may be prevented from occurring at the corner 20 since the sectional area of the corner 20 has been increased.

In addition, a sectional area extending from the stress concentration portion 21 is relatively larger than areas extending from other portions (e.g., R1 and R2), since the stress concentration portion 21 bulges out from a surface near those points. Therefore, even if a stress is concentrated to the stress concentration portion 21, the stress concentration portion 21 will also be protected from cracking.

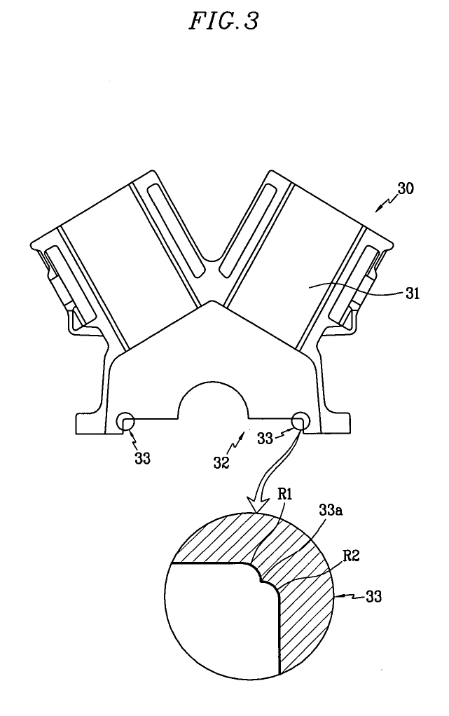

As shown in FIG. 3, an engine cylinder block 30 includes a cylinder 31, and a mounting part 32 for a bearing cap. Comers 33 are formed in the mounting part 32 for the bearing cap. Accordingly, the above-described structure for preventing stress concentration in a corner according to an embodiment of the present invention may be applied to the corners 33 of the mounting part 32 for the bearing cap. In more detail, as shown in FIG. 3, the corner 33 of the mounting part 32 for a bearing cap includes the stress concentration portion 33a, and a plurality of round portions R1 and R2. Accordingly, a sectional area of the corner 33 of the mounting part 32 for a bearing cap becomes enlarged, and therefore, a crack may be prevented from occurring at the corner 33.

According to an embodiment of the present invention, because the cross-sectional area of the corner is enlarged, durability of the corner may be enhanced. In addition, a rolling machine and a rolling process that are expensive are not required, and therefore, such an enhanced durability of a corner may be achieved at a low cost.

While this invention has been described in connection with what is presently considered to be the most practical and preferred embodiment, it is to be understood that the invention is not limited to the disclosed embodiments, but, on the contrary, is intended to cover various modifications and equivalent arrangements included within the spirit and scope of the appended claims.

1. A structure for preventing stress concentration in a corner, comprising:
a stress concentration portion formed to at least one point in the corner to concentrate stress; and
a plurality of round portions formed to both sides with respect to the stress concentration portion such that a sectional area of the stress concentration portion may be enlarged.

2. The structure for preventing stress concentration in a corner of claim 1, wherein the stress concentration portion is formed at a center of the corner such that stress is unbiased.

3. The structure for preventing stress concentration in a corner of claim 2, wherein the plurality of round portions comprise first and second round portions of a same size that are respectively formed at the left and right sides of the stress concentration portion.

4. A structure for preventing stress concentration in an inwardly formed corner, comprising a central extending portion with radiused portions on opposite sides.

5. The structure of claim 4, wherein the central extending portion is centered within the corner.

6. The structure of claim 5, wherein the radiused portions have equal radii.

7. A structure for relieving stress concentrations in engine assemblies, comprising:
an engine component formed to include at least one inward corner;
a portion extending outward from within the inwardly formed corner; and
radiused portions joining sides of the extending portion with the sides of the corner.

8. The structure of claim 7, wherein the extending portion is at least substantially pointed.

9. The structure of claim 7, wherein the extending portion is centered within the corner.

10. The structure of claim 9, wherein the radiused portions have equal radii.
